(19) United States
(12) Patent Application Publication
(10) Pub. No.: US 2008/0048728 A1
(43) Pub. Date: Feb. 28, 2008

(54) STABLE SENSE AMPLIFIER

(75) Inventors: Sang-Pyo HONG, Gyeonggi-do (KR); Jun-Hee LIM, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/845,693

(22) Filed: Aug. 27, 2007

(30) Foreign Application Priority Data
Aug. 25, 2006 (KR) 10-2006-0081246

(51) Int. Cl. H03F 3/45

(52) U.S. Cl. 327/51

(57) ABSTRACT

In an embodiment, a sense amplifier can perform a stable differential amplifying operation while having a high differential amplification gain. The sense amplifier comprises a current sense amplification unit, a voltage difference amplification unit, and an output stabilization unit. The current sense amplification unit receives differential input currents and generates differential output voltages corresponding to the differential input currents. The voltage difference amplification unit amplifies a voltage level difference between the differential output voltages through positive feedback using cross-coupled transistors. The output stabilization unit connects output stabilizing elements having a positive input resistance in parallel with the voltage difference amplification unit having a negative input resistance to stabilize the output of the voltage difference amplification unit.

### CROSS-REFERENCE TO RELATED PATENT APPLICATION

This application claims the benefit of Korean Patent Application No. 10-2006-0081246, filed on Aug. 25, 2006, in the Korean Intellectual Property Office, the disclosure of which is incorporated herein in its entirety by reference.

### BACKGROUND

1. Field of the Invention

The present invention relates to a sense amplifier to perform a stable sense amplifying operation and an input/output (I/O) sense-amplifying apparatus including the same, and more particularly, to a sense amplifier having a high differential amplification gain and performing a stable differential amplifying operation and an I/O sense-amplifying apparatus including the same.

2. Description of the Related Art

A sense amplification system is used in data input/output operations of a semiconductor memory device. The sense amplification system includes a bit line sense amplifier that transfers data through a bit line and an I/O sense amplifier that transfers data through an I/O line.

FIG. 1 is a block diagram of a sense amplification system of a semiconductor memory device. Referring to FIG. 1, the sense amplification system includes a bit line sense amplifier 110 and an I/O sense-amplifying apparatus 120. The I/O sense-amplifying apparatus 120 includes an I/O sense amplifier 130 controlled by an enable signal S1 and an equalizing control signal S2, a differential amplifier 140 controlled by an enable signal S3, a latch 150 controlled by an enable signal S4, and an output driver 160.

As the chip density of semiconductor memory devices increases, a current mode sense amplifier is used as the I/O sense amplifier 130 to prevent a decreasing data line transmission rate. Furthermore, because operating voltages of semiconductor memory devices are continuously decreasing, the I/O sense amplifier 130 needs to have a high differential amplification gain at a low operating voltage.

FIG. 2 illustrates a conventional current mode sense amplifier 230 that includes cross-coupled transistors P1 and P2, a transfer gate TG that connects or disconnects a first output node N_out1 and a second output node N_out2 to or from each other, an inverter INV, a diode-connected transistor N1, a diode-connected transistor N2, and a transistor NE operating in response to an enable signal S1.

The current mode sense amplifier 230 generates differential output voltages Vout1 and Vout2 respectively corresponding to differential input currents Iin1 and Iin2. As the difference between the first and second output voltages Vout1 and Vout2 increases, the differential amplification gain of the current mode sense amplifier 230 increases.

In detail, the differential amplification gain of the current mode sense amplifier 230 increases as the input resistances Rin1 and Rin2 decrease and the transconductance of the diode-connected transistors N1 and N2 decrease. This is because the differential input currents Iin1 and Iin2 face less input resistance as the input resistances Rin1 and Rin2 decrease. The voltage level difference between the first and second output voltages Vout1 and Vout2 increases as the transconductances of the diode-connected transistors N1 and N2 decrease (that is, as the input resistances of the diode-connected transistors N1 and N2 increase). However, when the transconductances of the diode-connected transistors N1 and N2 excessively decrease, the input resistances Rin1 and Rin2 have negative values that result in an unstable differential amplifying operation of the current mode sense amplifier 230. This makes it difficult for the current mode sense amplifier 230 to have a high differential amplification gain at a low operating voltage.

### SUMMARY

Embodiments of the present invention include a sense amplifier capable of performing a stable differential amplifying operation while having a high differential amplification gain even at a low operating voltage.

According to an aspect of the present invention, a sense amplifier comprises a current sense amplification unit, a voltage difference amplification unit, and an output stabilization unit. The current sense amplification unit receives differential input currents and generates first and second differential output voltages corresponding to the differential input currents. The voltage difference amplification unit amplifies a difference between the first and second differential output voltages through positive feedback using cross-coupled first and second transistors and cross-coupled third and fourth transistors. The output stabilization unit connects output stabilizing elements having a positive input resistance in parallel with the voltage difference amplification unit having a negative input resistance to stabilize the output of the voltage difference amplification unit.

A total input resistance of the voltage difference amplification unit and the output stabilization unit connected in parallel may have a positive value. The absolute value of the input resistance of the output stabilizing unit may be smaller than the absolute value of the input resistance of the voltage difference amplification unit.

The output stabilization unit may use diode-connected transistors or resistors as the output stabilization elements.

In an embodiment, the first transistor has a first terminal connected to a node to receive a first power voltage, a second terminal connected to a first output node to output the first differential output voltage, and a control terminal connected to a second output node to output the second differential output voltage The second transistor has a first terminal connected to the node to receive the first power voltage, a second terminal connected to the second output node, and a control terminal connected to the first output node. The third transistor has a first terminal connected to a node to receive a second power voltage, a second terminal connected to the first output node, and a control terminal connected to the second output node. And the fourth transistor has a first terminal connected to the node to receive the second power voltage, a second terminal connected to the second output node, and a control terminal connected to the first output node.

In another embodiment, the sense amplifier may further comprise an equalization controller to connect or disconnect the first and second output nodes to or from each other in response to an equalizing control signal.

The voltage difference amplification unit may further comprise a first power transistor to transfer the first power voltage to the node receiving the first power voltage in response to the equalizing control signal, and a second power transistor to transfer the second power voltage to the node receiving the second power voltage in response to the equalizing control signal.

The equalization controller may transfer the equalizing control signal to the second power transistor that is an N-type MOSFET, invert the equalizing control signal, and transfer the inverted equalizing control signal to the first power transistor that is a P-type MOSFET, and connect or disconnect the first and second output nodes to or from each other using a transfer gate operating in response to the equalizing control signal.

According to another aspect of the present invention, an I/O sense-amplifying apparatus outputs a data voltage corresponding to data from a bit line sense amplifier, which comprises a sense amplifier receiving differential input currents that represent the data and outputs first and second differential output voltages corresponding to the differential input currents. An output driver outputs the data voltage generated from the first and second differential output voltages to an external device. The sense amplifier comprises a current sense amplification unit receiving the differential input currents and generating the first and second differential output voltages, a voltage difference amplification unit amplifying a voltage level difference between the first and second differential output voltages through positive feedback using cross-coupled first and second transistors and cross-coupled third and fourth transistors, and an output stabilization unit connecting output stabilizing elements having a positive input resistance in parallel with the voltage difference amplification unit having a negative input resistance to stabilize the output of the voltage difference amplification unit.

The first and second differential output voltages output from the sense amplifier may be directly transferred to the output driver or transferred to the output driver via a latch.

The data voltage may be generated based on the first and second differential output voltages after the voltage level difference between the first and second differential output voltages has been developed to more than a predetermined value.

### BRIEF DESCRIPTION OF THE DRAWINGS

The above and other features and advantages of the present invention will become more apparent by describing in detail exemplary embodiments with reference to the attached drawings.

FIG. 1 is a block diagram of a conventional sense amplification system for a semiconductor memory device.

FIG. 2 is a circuit diagram of a conventional current mode sense amplifier.

FIG. 3 is a circuit diagram of a sense amplifier having a current mode amplifier and a voltage mode amplifier that are combined with each other.

FIG. 4 is a circuit diagram of a sense amplifier according to an embodiment.

FIG. 5A illustrates differential output voltages of the current mode sense amplifier illustrated in FIG. 2 and differential output voltages of the sense amplifier illustrated in FIG. 4.

FIG. 5B illustrates currents consumed in the sense amplifiers of FIGS. 2 and 4.

FIG. 6A is a block diagram of an I/O sense-amplifying apparatus according to an embodiment.

FIG. 6B is a block diagram of an I/O sense-amplifying apparatus according to another embodiment.

### DETAILED DESCRIPTION OF THE EMBODIMENTS

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. Throughout the drawings, like reference numerals refer to like elements.

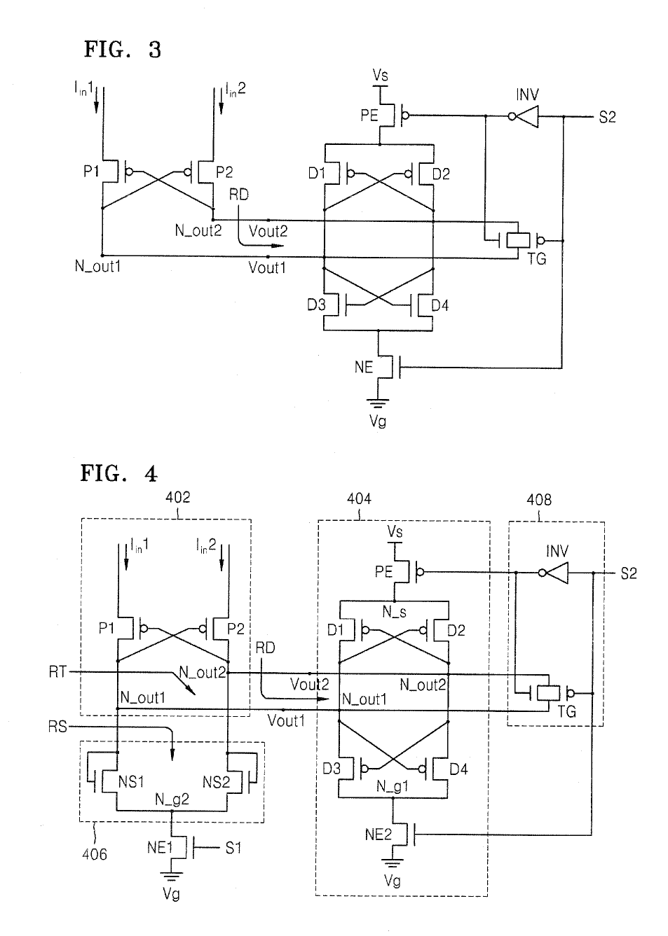

FIG. 3 is a circuit diagram of a sense amplifier having a current mode amplifier and a voltage mode amplifier, which are combined with each other. The sense amplifier of this embodiment includes cross-coupled transistors P1 and P2, cross-coupled first and second transistors D1 and D2, cross-coupled third and fourth transistors D3 and D4, a first power transistor PE having a first terminal connected to a first power source Vs, a second power transistor NE having a first terminal connected to a second power voltage source Vg, a transfer gate TG connecting or disconnecting first and second output nodes N_out1 and N_out2 to or from each other in response to an equalizing control signal S2, and an inverter INV.

The cross-coupled transistors P1 and P2 function as a current mode sense amplifier. The cross-coupled first and second transistors D1 and D2, the cross-coupled third and fourth transistors D3 and D4, the first power transistor PE, and the second power transistor NE function as a voltage mode sense amplifier. The first power transistor PE, the second power transistor NE and the transfer gate TG are turned on or turned off in response to the logic level of the equalizing control signal S2.

Differential input currents Iin1 and Iin2 respectively pass through the cross-coupled transistors P1 and P2 to generate first and second differential output voltage Vout1 and Vout2. The first and second differential output voltage Vout1 and Vout2 are input to the voltage mode sense amplifier to be amplified differentially. When the first differential output voltage Vout1 is higher than the second differential output voltage Vout2, the first differential output voltage Vout1 further increases and the second differential output voltage Vout2 further decreases according to the voltage mode differential amplifying operation. The first and second differential output voltages Vout1 and Vout2 that have been subjected to the differential amplification are respectively output through first and second output nodes N_out1 and N_out2.

As described above, the differential amplification gain of the sense amplifier can be increased by combining the current mode sense amplifier with the voltage mode sense amplifier. However, an input resistance RD of the voltage mode sense amplifier including the cross-coupled transistors D1, D2, D3, and D4 may have a negative value that decreases the stability of the sense amplifier. That is, combining the current mode sense amplifier with the voltage mode sense amplifier can improve the differential amplification gain of the sense amplifier, but the output characteristics of the sense amplifier can become unstable due to the high differential amplification gain. Embodiments of the present invention solve this problem in consideration of both the differential amplification gain and stability.

FIG. 4 is a circuit diagram of a sense amplifier according to an embodiment. The sense amplifier includes a current sense amplification unit 402, a voltage difference amplification unit 404, and an output stabilization unit 406. The sense amplifier may further include an equalization controller 408.

The current sense amplification unit 402 includes cross-coupled transistors P1 and P2.

In the embodiment, the voltage difference amplification unit 404 includes cross-coupled first and second transistors D1 and D2, cross-coupled third and fourth transistors D3 and D4, a first power transistor PE connected between a source of a first power voltage Vs, and a node N_s receiving the first power voltage Vs, and a second power transistor NE2 connected between a source of a second power voltage Vg and a node N_g 1 receiving the second power voltage Vg. The output stabilization unit 406 includes a transistor NS1 diode-connected between a first output node N_out1 and a node N_g2 and a transistor NS2 diode-connected between a second output node N_out2 and the node N_g2. The node N_g2 is connected or disconnected to or from the source of the second power voltage Vg through a transistor NE1 operating in response to an enable signal S1.

The equalization controller 408 includes an inverter INV receiving an equalizing control signal S2 and a transfer gate TG.

The current sense amplification unit 402 receives differential input currents Iin1 and Iin2 and in turn generates differential output voltages Vout1 and Vout2 respectively corresponding to the differential input currents Iin1 and Iin2. The differential output voltages Vout1 and Vout2 are input to the voltage difference amplification unit 404.

The voltage difference amplification unit 404 amplifies a voltage level difference between the differential output voltages Vout1 and Vout2 through positive feedback using the cross-coupled first and second transistors D1 and D2 and the cross-coupled third and fourth transistors D3 and D4. Through the positive feedback, a relatively high voltage Vout1 or Vout2 of the differential output voltages Vout1 and Vout2 is further increased and a relatively low voltage Vout2 or Vout1 is further decreased. In other words, the respective values Vout1 and Vout2 diverge, thus increasing their respective difference. The differential output voltages Vout1 and Vout2 that have been subjected to the differential amplification of the voltage difference amplification unit 404 are respectively output through the first and second output nodes N_out1 and N_out2.

Describing the voltage difference amplification unit 404 in detail, the first transistor D1 has a first terminal connected to the node N_s receiving the first power voltage Vs, a second terminal connected to the first output node N_out1 outputting the first differential output voltage Vout1, and a control terminal connected to the second output node N_out2 outputting the second differential output voltage Vout2. The second transistor D2 has a first terminal connected to the node N_s receiving the first power voltage Vs, a second terminal connected to the second output node N_out2, and a control terminal connected to the first output node N_out1. The third transistor D3 has a first terminal connected to the node N_g1 receiving the second power voltage Vg, a second terminal connected to the first output node N_out1, and a control terminal connected to the second output node N_out2. The fourth transistor D4 has a first terminal connected to the node N_g1 receiving the second power voltage Vg, a second terminal connected to the second output node N_out2, and a control terminal connected to the first output node N_out1.

As illustrated in FIG. 4, the voltage difference amplification unit 404 may further include the first power transistor PE transferring the first power voltage Vs to the node N_s in response to the equalizing control signal S2, and the second power transistor NE2 transferring the second power voltage Vg to the node N_g1.

When the output of the voltage difference amplification unit 404 is stabilized, the sense amplifier can perform a stable differential amplifying operation.

Thus, the sense amplifier according to an embodiment includes the output stabilization unit 406 for stabilizing the output of the voltage difference amplification unit 404.

Describing in general terms, the output stabilization unit 406 connects an output stabilizing element having a positive input resistance in parallel with the voltage difference amplification unit 404 having a negative input resistance to stabilize the output of the voltage difference amplification unit 404. That is, the output stabilization unit 406 makes the total input resistance RT of the voltage difference amplification unit 404 and the output stabilization unit 406 have a positive value so that the sense amplifier can perform a stable differential amplifying operation. When the total input resistance RT of the voltage difference amplification unit 404 and the output stabilization unit 406 is a positive value, the differential amplification of the sense amplifier is stabilized.

Since the voltage difference amplification unit 404 and the output stabilization unit 406 are connected in parallel with each other, the total input resistance RT of the voltage difference amplification unit 404 and the output stabilization unit 406 is calculated as follows.

$$\begin{matrix}RT = RD // RS \\ = ( RD * RS ) / ( RD + RS )\end{matrix}$$

Here, the product (RD*RS) has a negative value because the input resistance RD of the voltage difference amplification unit 404 is negative and the input resistance RS of the output stabilization unit 406 is positive. In this case, when the absolute value of the input resistance RS of the output stabilization unit 406 is smaller than the absolute value of the input resistance RD of the voltage difference amplification unit 404, the sum (RD+RS) is negative and thus the total input resistance RT of the voltage difference amplification unit 404 and the output stabilization unit 406 has a positive value, resulting in a stabilized differential amplification.

While FIG. 4 illustrates the N-type diode-connected transistors NS1 and NS2 as output stabilizing elements, the invention is not limited to their use. For example, P-type diode-connected transistors or resistors may be used as the output stabilizing elements. As illustrated in FIG. 4, the output stabilizing elements are respectively inserted between the first output node N_out1 and the node N_g2 and between the second output node N_out2 and the node N_g2.

While FIG. 4 illustrates the current sense amplification unit 402 and the output stabilization unit 406 as separate components, the output stabilization unit 406 participates in the differential amplification of the current sense amplification unit 402 (to generate the differential output voltages from the differential input currents) in addition to the operation of stabilizing the output of the voltage difference amplification unit 404, and thus the output stabilization unit 406 may be considered as a component included in the current sense amplification unit 402. In practice, of course, the current sense amplification unit 402 and the output stabilization unit 406 may be separate or integral, as one skilled in the art understands there are no limitations to their construction.

The equalization controller 408 connects or disconnects the first and second output nodes N_out1 and N_out2 to or from each other in response to the equalizing control signal S2. The equalizing control signal S2 is transferred to the gate of the second power transistor NE2 that is an N-type MOSFET. In addition, the equalizing control signal S2 is transferred to the gate of the first power transistor PE that is a P-type MOSFET via the inverter INV. The transfer gate TG connects or disconnects the first and second output nodes N_out1 and N_out2 to or from each other in response to the equalizing control signal S2.

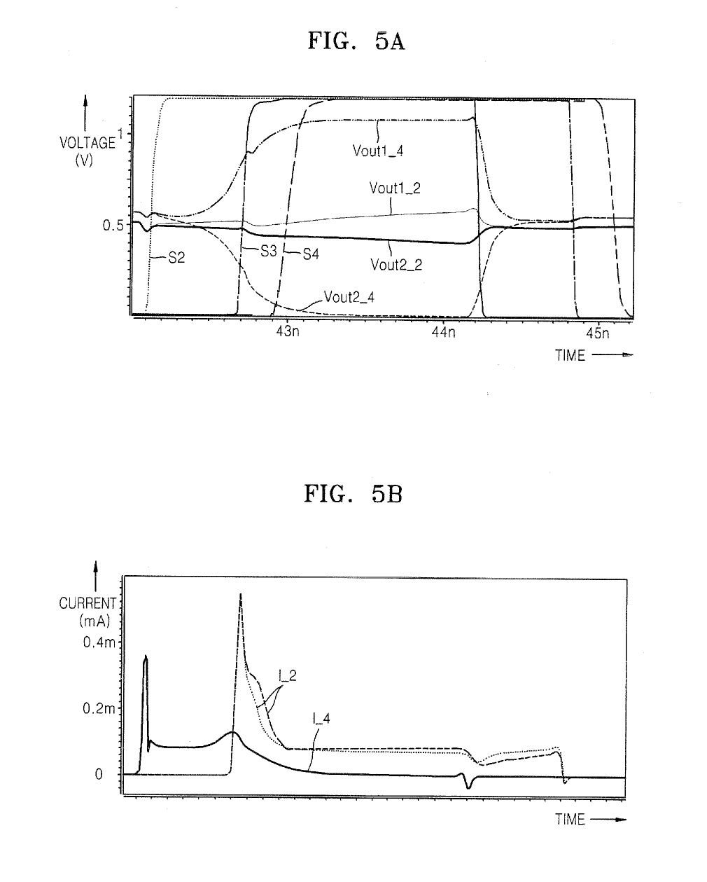

FIG. 5A illustrates and compares the performance of the conventional sense amplifier with that of the novel one described in the present embodiment. The figure shows differential output voltages Vout1_2 and Vout2_2 of the conventional current mode sense amplifier illustrated in FIG. 2 and differential output voltages V_out1_4 and Vout2_4 of the novel sense amplifier illustrated in FIG. 4. The vertical axis indicates a voltage V and the horizontal axis indicates time.

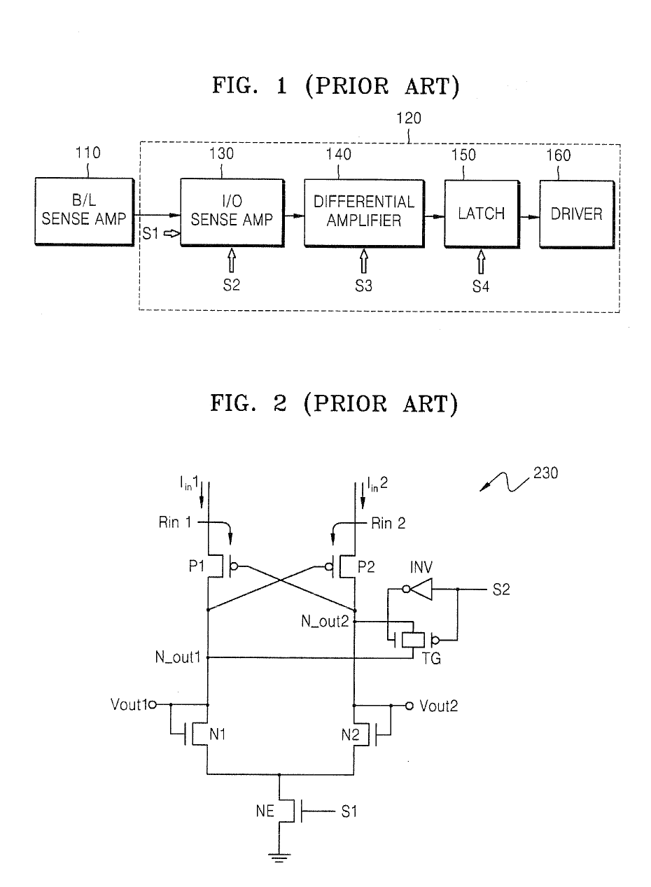

FIG. 5A illustrates a case where the first output voltages Vout1_2 and Vout1_4 are higher than the second output voltages Vout2_2 and Vout2_4. S2, S3 and S4 respectively indicate the equalizing control signal S2, the enable signal S3, and the enable signal S4 illustrated in FIG. 1.

The voltage level difference between the first and second output voltages Vout1_4 and Vout2_4 of the novel sense amplifier illustrated in FIG. 4 is greater than the voltage level difference between the first and second output voltages Vout1_2 and Vout2_2 of the conventional sense amplifier illustrated in FIG. 2. A large voltage difference means a high differential amplification gain. Accordingly, the sense amplifier according to the present embodiment has an improved differential amplification gain.

Furthermore, in the sense amplifier according to the present embodiment, the time required for the voltage level difference between the first and second output voltages Vout1_4 and Vout2_4 to be developed to higher than a predetermined value is reduced compared to that of the conventional sense amplifier. This means a delay time reduction. Accordingly, the novel sense amplifier has an improved timing margin.

FIG. 5B illustrates another comparison between the conventional and novel arts. The figure shows a current I_2 consumed in the conventional sense amplifier of FIG. 2 and a current I_4 consumed in the novel sense amplifier of FIG. 4. The vertical axis indicates current and the horizontal axis indicates time.

The current I_4 consumed in the novel sense amplifier illustrated in FIG. 4 is much smaller than the current I_2 consumed in the conventional sense amplifier illustrated in FIG. 2. Furthermore, the current I_4 approximates to zero after the voltage level difference between the differential output voltages Vout1_4 and Vout2_4 is developed to higher than the predetermined value. That is, the sense amplifier according to an embodiment of the present invention has an advantage in terms of current consumption.

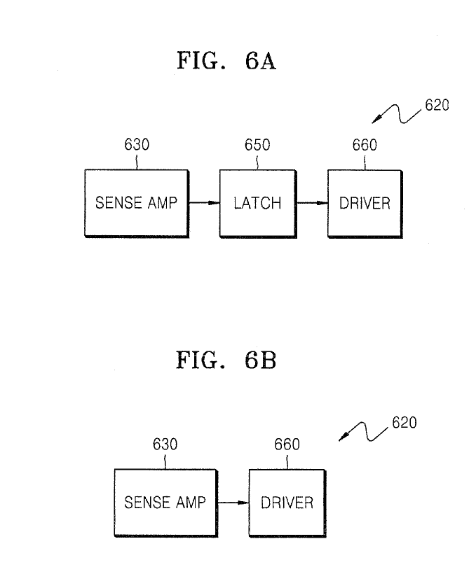

FIGS. 6A and 6B are block diagrams of I/O sense-amplifying apparatuses 620 according to several embodiments. FIG. 6A illustrates an I/O sense-amplifying apparatus 620 including a sense amplifier 630, a latch 650, and an output driver 660. FIG. 6B illustrates an I/O sense-amplifying apparatus 620 including the sense amplifier 630 and the output driver 660. In both illustrated embodiments, the sense amplifier 630 corresponds to the sense amplifier illustrated in FIG. 4.

The I/O sense-amplifying apparatus 620 outputs an output data voltage corresponding to data from a bit line sense amplifier (110 illustrated in FIG. 1, for example). The sense amplifier 630 receives differential input currents representing the data and outputs differential output voltages corresponding to the differential input currents. The output driver 660 outputs the output data voltage generated from the differential output voltages to an external device.

The sense amplifier 630 including the components as illustrated in FIG. 4 has a high differential amplification gain as described with reference to FIG. 5A. Thus, the I/O sense-amplifying apparatus 620 does not require a component such as the differential amplifier 140 illustrated in FIG. 1. Accordingly, the differential output voltages output from the sense amplifier 630 are transferred to the output driver 660 via the latch 650, as illustrated in FIG. 6A, or directly transferred to the output driver 660, as illustrated in FIG. 6B.

Furthermore, when the sense amplifier 630 is tuned so that the voltage level difference between the differential output voltages approximates to the voltage level difference between the first power voltage Vs and the second power voltage Vg (Refer to FIG. 4), the latch 650 can be removed from the input/output sense-amplifying apparatus 620, as illustrated in FIG. 6B. Removing the differential amplifier or the latch allows a reduction of the chip area of the I/O sense-amplifying apparatus 620.

The data voltage output from the output driver 660 is generated based on the differential output voltages after the voltage level difference between the differential output voltages has been developed to higher than a predetermined threshold value.

As described earlier, the sense amplifier 630 includes the current sense amplification unit 402, the voltage difference amplification unit 404, and the output stabilization unit 406 as illustrated in FIG. 4. The sense amplifier 630 may further include the equalization controller 408 as illustrated in FIG. 4.

As also described above, the total input resistance RT of the output stabilization unit 406 and the voltage difference amplification unit 404 has a positive value. The output stabilization unit 406 can use a diode-connected transistor or a resistor as an output stabilizing element.

According to the present embodiment, the sense amplifier can perform a stable differential amplifying operation while having a high differential amplification gain. Furthermore, a time required for a voltage level difference between differential voltages output from the sense amplifier to be developed to higher than a predetermined value is reduced. In addition, a very small current is consumed in the sense amplifier after the voltage level difference between the differential output voltages has been developed to higher than the predetermined value. Moreover, an I/O sense-amplifying apparatus that does not require a differential amplifier and a latch can be constructed because the sense amplifier has a high differential amplification gain. This reduces the chip area of the I/O sense-amplifying apparatus.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A sense amplifier comprising:
a current sense amplification unit to receive differential input currents and to generate first and second differential output voltages that correspond to the differential input currents;
a voltage difference amplification unit to amplify a voltage level difference between the first and second differential output voltages through positive feedback using cross-coupled first and second transistors and cross-coupled third and fourth transistors; and
an output stabilization unit connecting output stabilizing elements having a positive input resistance in parallel with the voltage difference amplification unit having a negative input resistance to stabilize the output of the voltage difference amplification unit.

2. The sense amplifier of claim 1, wherein a total input resistance of the voltage difference amplification unit and the output stabilization unit connected in parallel is positive.

3. The sense amplifier of claim 2, wherein the absolute value of the input resistance of the output stabilization unit is smaller than the absolute value of the input resistance of the voltage difference amplification unit.

4. The sense amplifier of claim 3, wherein the output stabilization unit connects diode-connected transistors to nodes to respectively output the first and second differential output voltages to use the diode-connected transistors as the output stabilizing elements.

5. The sense amplifier of claim 3, wherein the output stabilization unit connects resistors to nodes to respectively output the first and second differential output voltages to use the resistors as the output stabilizing elements.

6. The sense amplifier of claim 1, wherein the first transistor comprises:
a first terminal connected to a node that receives a first power voltage;
a second terminal connected to a first output node that outputs the first differential output voltage; and
a control terminal connected to a second output node that outputs the second differential output voltage, wherein the second transistor comprises:
a first terminal connected to the node that receives the first power voltage;
a second terminal connected to the second output node; and
a control terminal connected to the first output node, wherein the third transistor comprises:
a first terminal connected to a node that receives a second power voltage;
a second terminal connected to the first output node; and
a control terminal connected to the second output node, and wherein the fourth transistor comprises:
a first terminal connected to the node that receives the second power voltage;
a second terminal connected to the second output node; and
a control terminal connected to the first output node.

7. The sense amplifier of claim 6, further comprising an equalization controller to connect or disconnect the first and second output nodes to or from each other in response to an equalizing control signal.

8. The sense amplifier of claim 7, wherein the voltage difference amplification unit further comprises:
a first power transistor to transfer the first power voltage to the node that receives the first power voltage in response to the equalizing control signal; and
a second power transistor to transfer the second power voltage to the node that receives the second power voltage in response to the equalizing control signal.

9. The sense amplifier of claim 8, wherein the equalization controller is configured to transfer the equalizing control signal to the second power transistor that is an N-type MOSFET, to invert the equalizing control signal, and to transfer the inverted equalizing control signal to the first power transistor that is a P-type MOSFET, wherein the equalization controller connects or disconnects the first and second output nodes to or from each other using a transfer gate operating in response to the equalizing control signal.

10. An I/O sense-amplifying apparatus for outputting a data voltage corresponding to data from a bit line sense amplifier, the apparatus comprising:
a sense amplifier to receive differential input currents that represent the data and to output first and second differential output voltages; and
an output driver to output the data voltage generated from the first and second differential output voltages to an external device,
wherein the sense amplifier comprises:
a current sense amplification unit to receive the differential input currents and to generate the first and second differential output voltages;
a voltage difference amplification unit to amplify a voltage level difference between the first and second differential output voltages through positive feedback using cross-coupled first and second transistors and cross-coupled third and fourth transistors; and
an output stabilization unit that connects output stabilizing elements having a positive input resistance in parallel with the voltage difference amplification unit having a negative input resistance to stabilize the output of the voltage difference amplification unit.

11. The I/O sense-amplifying apparatus of claim 10, wherein the first and second differential output voltages are directly transferred from the sense amplifier to the output driver.

12. The I/O sense-amplifying apparatus of claim 10, wherein the first and second differential output voltages are transferred from the sense amplifier to the output driver via a latch.

13. The I/O sense-amplifying apparatus of claim 10, wherein the data voltage is generated based on the voltage level difference between the first and second differential output voltages after the voltage level difference has been developed to more than a predetermined threshold value.

14. The I/O sense-amplifying apparatus of claim 10, wherein a total input resistance of the output stabilization unit and the voltage difference amplification unit is positive.

15. The I/O sense-amplifying apparatus of claim 14, wherein the output stabilization unit uses diode-connected transistors or resistors as the output stabilizing elements.

16. The I/O sense-amplifying apparatus of claim 10, wherein the first transistor has a first terminal connected to a node receiving a first power voltage, a second terminal connected to a first output node outputting the first differential output voltage and a control terminal connected to a second output node outputting the second differential output voltage, the second transistor has a first terminal connected to the node receiving the first power voltage, a second terminal connected to the second output node and a control terminal connected to the first output node, the third transistor has a first terminal connected to a node receiving a second power voltage, a second terminal connected to the first output node and a control terminal connected to the second output node, and the fourth transistor has a first terminal connected to the node receiving the second power voltage, a second terminal connected to the second output node and a control terminal connected to the first output node.

17. The I/O sense-amplifying apparatus of claim 16, wherein the voltage difference amplification unit further comprises:
a first power transistor transferring the first power voltage to the node receiving the first power voltage; and
a second power transistor transferring the second power voltage to the node receiving the second power voltage.

18. The I/O sense-amplifying apparatus of claim 17, further comprising an equalization controller connecting or disconnecting the first and second output nodes to or from each other in response to an equalizing control signal and turning on or off the first power transistor and the second power transistor in response to the equalizing control signal.

19. A method of amplifying differential input currents in a semiconductor memory device, the method comprising:
generating first and second differential output voltages that correspond to the differential input currents;
amplifying a voltage level difference between the first and second differential output voltages through positive feedback in a circuit portion having a negative input resistance; and
connecting output stabilizing elements having a positive input resistance in parallel with the circuit portion having the negative input resistance to stabilize the amplifying operation.

20. The method of claim 19, wherein the circuit portion includes cross-coupled first and second transistors and cross-coupled third and fourth transistors.

21. The method of claim 19, wherein a total input resistance of the circuit portion and the output stabilizing elements connected in parallel has a positive value.

22. The method of claim 19, further comprising generating a data voltage based on the voltage level difference between the first and second differential output voltages after the voltage level difference has been developed to more than a predetermined threshold value.
